(19) United States
(12) Patent Application Publication
(10) Pub. No.: US 2005/0101140 A1
(43) Pub. Date: May 12, 2005

(54) Method of plasma etching

(75) Inventors: Tomoyo Yamaguchi, Yamanashi (JP); Kiwamu Fujimoto, Yamanashi (JP); Akinori Kitamura, Yamanashi (JP); Jae Young Jeong, Yamanashi (JP); Takashi Fuse, Yamanashi (JP); Machiko Obi, Yamanashi (JP); Nobuhiro Wada, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/949,366

(22) Filed: Sep. 27, 2004

Related U.S. Application Data
(63) Continuation of application No. PCT/JP03/02750, filed on Mar. 7, 2003.

(30) Foreign Application Priority Data
Mar. 25, 2002 (JP) 2002-082717

(51) Int. Cl. H01L 21/302; H01L 21/461; H01L 21/311

(52) U.S. Cl. 438/690

(57) ABSTRACT

A plasma etching method includes the steps of exciting an etching gas introduced in a processing vessel into a plasma, the etching gas including 1,1,1,4,4,5,5,5-octafluoro-2-pentyne, and carrying out a plasma etching on a film on a target object accommodated in the processing vessel via opening patterns of a resist mask on the film. Therefore, it is possible to perform plasma etching having a high selectivity to resist and/or suppressing the etch stop.

This application is a Continuation Application of PCT International Application No. PCT/JP03/02750 filed on Mar. 7, 2003, which designated the United States.

### FIELD OF THE INVENTION

The present invention relates to a method of plasma etching in the fabrication process of a semiconductor device.

### BACKGROUND OF THE INVENTION

Conventionally, as an etching gas for plasma etching a SiO₂ film on a substrate to be processed via opening patterns of a photoresist mask, a gas species such as fluorocarbon gas, particularly, a high order species gas such as C₄F₆ or C₄F₈, cyclo-C₅F₈ (octafluorocyclopentyne) and the like as the major component has been used, so as to achieve a high selectivity of SiO₂ film (etching rate of SiO₂ film/etching rate of photoresist) over photoresist material and to improve the quality of microprocessing.

However, for a gas species containing C₄F₆, C₄F₈, cyclo-C₅F₈ and the like as the major component, it is not possible to improve the photoresist selectivity while trying to maintain better microprocessing results.

Further, in case of using a gas species containing C₄F₆, C₄F₈, cyclo-C₅F₈ and the like as the major component, if the amount of C₄F₆, C₄F₈, cyclo-C₅F₈ is increased to achieve a higher etching rate, as etching proceeds, etching byproducts become deposited in etching holes, thereby lowering the etching rate. The etching rate would continuously slow down and arrive at so-call etch stop, where the etching process is finally terminated.

### SUMMARY OF THE INVENTION

The present invention has been developed with such background. It is therefore an object of the present invention to provide a plasma etching method having a high selectivity to photoresist and/or capable of suppressing an etch stop.

In accordance with a preferred embodiment of the present invention, there is provided a plasma etching method, including the steps of: exciting an etching gas introduced in a processing vessel into a plasma, the etching gas including an aliphatic C₅F₈ but not including CO; and carrying out a plasma etching on a film on a target object accommodated in the processing vessel via opening patterns of a resist mask disposed on the film, wherein the aliphatic C₅F₈ is 1,1,1,4,4,5,5,5-octafluoro-2-pentyne.

It is not preferable that CO is included in the etching gas containing the aliphatic C₅F₈ as a major component, since the etch stop is likely to occur. Accordingly, in accordance with the present invention, a plasma of the etching gas including the aliphatic C₅F₈ but not including CO is used, so that a plasma etching having a high selectivity to photoresist and/or capable of suppressing an etch stop is realized.

Here, the etching gas may contain O₂, or contain He, Ne, Ar, N₂, or the like.

In accordance with another preferred embodiment of the present invention, there is provided a plasma etching method, including the steps of: exciting an etching gas introduced in a processing vessel into a plasma, the etching gas including an aliphatic C₅F₈, O₂, and an inert gas; and carrying out a plasma etching on a film on a target object accommodated in the processing vessel via opening patterns of a resist mask disposed on the film, wherein the aliphatic C₅F₈ is 1,1,1,4,4,5,5,5-octafluoro-2-pentyne.

As the aliphatic C₅F₈, the following may be acceptable: CF≡CC₃F₇ (1,3,3,4,4,5,5,5-octafluoro-1-pentyne), CF₃C≡CC₂F₅ (1,1,1,4,4,5,5,5-octafluoro-2-pentyne), CF₂═C═CFC₂F₅ (1,1,3,4,4,5,5,5-octafluoro-1,2-pentadiene), CF₂═CFCF═CFCF₃ (1,1,2,3,4,5,5,5-octafluoro-1,3-pentadiene), CF₂═CFCF₂CF═CF₂ (1,1,2,3,3,4,5,5-octafluoro-1,4-pentadiene), CF₃CF═C═CFCF₃ (1,1,1,2,4,5,5,5-octafluoro-2,3-pentadiene), or the like can be used. However, CF₃C≡CC₂F₅ is suitable for use, since it can be relatively easily produced.

In case where CF₃C≡CC₂F₅ is employed and the etching gas contains O₂, it is preferred that a flow rate ratio of the CF₃C≡CC₂F₅ to the O₂ is in the range from about 0.79 to about 1.12. If the ratio is less than about 0.79, a selectivity to resist becomes small and an etch stop is likely to occur. In fact, when the ratio was about 0.68 and less corresponding to a value less than about 0.79, a selectivity to resist became small. On the other hand, when the ratio was about 1.32 corresponding to a value greater than about 1.12, the etch stop was likely to occur. Even though the test is not performed in case where the ratio is about 1.32 or greater, it is considered that the etch stop is likely to occur, as the ratio is high. An inner pressure of a processing vessel is preferably greater than or equal to about 2.67 Pa (about 20 mTorr), and more preferably, about 2.67 to about 4 Pa (about 20 to about 30 mTorr).

In accordance with still another preferred embodiment of the present invention, there is provided a plasma etching method, including the steps of: exciting an etching gas introduced in a processing vessel into a plasma, the etching gas including 1,1,1,4,4,5,5,5-octafluoro-2-pentyne; and carrying out a plasma etching on a film on a target object accommodated in the processing vessel via opening patterns of a resist mask disposed on the film.

The etching gas may contain O₂. In this case, it is preferred that a flow rate ratio of the 1,1,1,4,4,5,5,5-octafluoro-2-pentyne to the O₂ is in the range from about 0.79 to about 1.12. Further, it is preferred that the CF₃C≡CC₂F₅ partial pressure is in the range from about 0.0746 to about 0.105 Pa (about 0.56 to about 0.79 mTorr). If the CF₃C≡CC₂F₅ partial pressure is less than about 0.0746 Pa, a selectivity to resist becomes small, and if it is greater than about 0.105 Pa, an etch stop is likely to occur. In fact, when the CF₃C≡CC₂F₅ partial pressure was about 0.0626 Pa (about 0.47 mTorr) or about 0.0653 Pa (about 0.49 mTorr) corresponding to a value smaller than about 0.0746 Pa, the selectivity to resist became small. On the other hand, when the CF₃C≡CC₂F₅ partial pressure was about 0.119 Pa (about 0.88 mTorr) corresponding to a value greater than about 0.105 Pa, the etch stop was likely to occur. Even though the test is not performed in case where the partial pressure is greater than about 0.119 Pa, it is considered that the etch stop is likely to occur, as the partial pressure is high.

While the etching gas may contain O₂, preferably, it does not contain CO, substantially. The reason is that the etch stop is likely to occur due to CO.

In the aforementioned preferred embodiments of the present invention, as a film to be etched, there may be used an oxide film (oxygen compound) such as SiO₂, TEOS, BPSG, PSG, SOG, thermal oxide film, HTO, FSG, organic silicon oxide film, CORAL (Novellus system), or the like; a low-k organic insulating film; or the like.

### BRIEF DESCRIPTION OF THE DRAWINGS

The above and other objects and features of the present invention will become apparent from the following description of preferred embodiments, given in conjunction with the accompanying drawings, in which:

FIG. 1 shows a schematic cross sectional view of a plasma etching apparatus in accordance with the present invention; and

FIG. 2 is a schematic cross-sectional view of the portion of a target object, which is subject to etching.

### DETAILED DESCRIPTION OF THE PREFERRED EMBODIMENT

Hereinafter, a preferred embodiment of the present invention will be described with reference to the accompanying drawings.

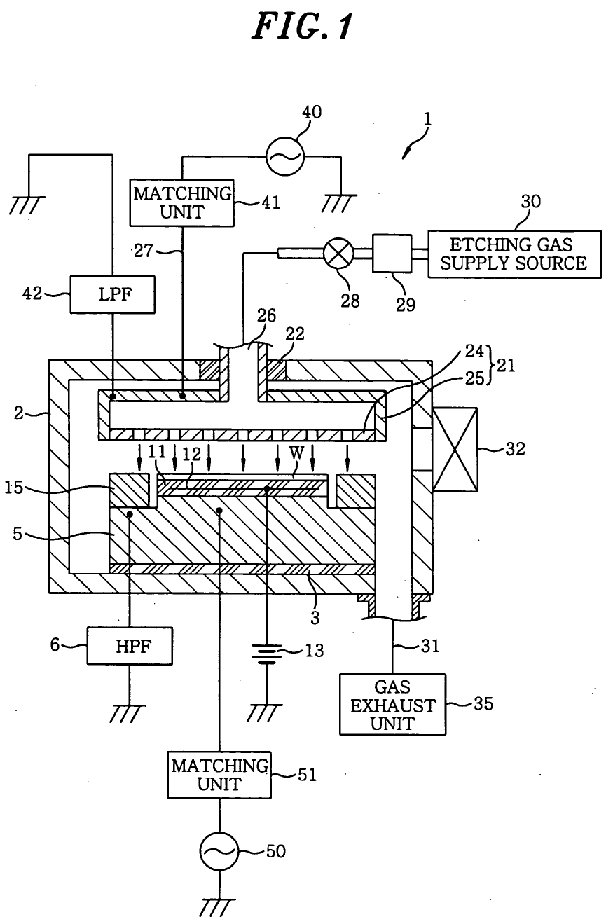

FIG. 1 shows a schematic cross sectional view of a plasma etching apparatus in accordance with the present invention. A processing vessel 2, which is frame grounded, is formed of metal, e.g., aluminum whose surface is oxidized. In the bottom portion inside the processing vessel 2, a susceptor 5 serving as a lower electrode of a parallel plate electrode is installed having an insulator 3 interposed between the susceptor and the bottom portion of the vessel. A high pass filter (HPF) 6 is connected to the susceptor 5. An electrostatic chuck 11 is installed on the susceptor 5, and a target object W, e.g., a semiconductor wafer or the like, is mounted on the electrostatic chuck. The electrostatic chuck 11 is formed of an insulator having an electrode 12 embedded therein, and electrostatically adsorbs the target object W by applying a DC voltage from a DC power supply 13 connected to the electrode 12. Further, a focus ring 15 is disposed such that it surrounds the target object W. The focus ring 15 is made of Si, SiO₂, or the like, and is there to improve etching uniformity.

Further, an upper electrode 21 is installed above the susceptor 5 so that the two electrodes face each other. The upper electrode 21 is fixed at the upper part of the processing vessel 2 via an insulator 22, and is formed of a showerhead-shaped electrode plate 24 and a supporter 25 for holding the electrode plate 24 in place.

In the central part of the supporter 25, a gas inlet port 26 is installed. To the gas inlet port 26, the following components are connected in the given order: a gas supply line 27, a valve 28, a mass flow controller 29, and an etching gas supply source 30. From the etching gas supply source 30, an etching gas including aliphatic C₅F₈ but without CO is supplied. Further, it is also acceptable that the etching gas contains O₂. As an aliphatic C₅F₈ species, as discussed above, the following are acceptable: CF≡CC₃F₇, CF₃C≡CC₂F₅, CF₂═C═CFC₂F₅, CF₂═CFCF═CFCF₃, CF₂═CFCF₂CF═CF₂, CF₃CF═C═CFCF₃, or the like can be used. However, CF₃C≡CC₂F₅ is preferable.

In case of using an etching gas containing CF₃C≡CC₂F₅ and O₂, it is preferred that a volumetric ratio of the CF₃C—CC₂F₅ to the O₂ [CF₃C≡CC₂F₅ flow rate)/[O₂ flow rate] is in the range from about 0.79 to about 1.12. Further, it is acceptable that the etching gas contains Ar.

In case of using the CF₃C≡CC₂F₅ as the aliphatic C₅F₈ species, although it is not necessary to exclude CO from the etching gas, still, it is preferable not to include CO. Further, in case of using the CF₃C≡CC₂F₅, it is preferable that the partial pressure of the species is in the range from about 0.0746 to about 0.105 Pa.

In addition, to the bottom part of the processing vessel 2, a gas exhaust line 31 is connected, and a gas exhaust unit 35 is connected to the gas exhaust line 31. Further, a gate valve 32 is disposed in the sidewall of the processing vessel 2, so that the target object W can be transported to a neighboring load-lock chamber (not shown).

To the upper electrode 21, a low pass filter (LPF) 42 and a first high frequency power source 41 via a matching unit 41 are connected, respectively. A second high frequency power source 50 is connected to the susceptor 5, which is the lower electrode, via a matching unit 51.

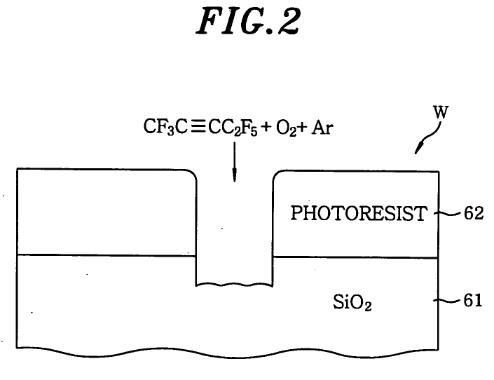

Hereinafter, a process for plasma etching of a SiO₂ film 61 on the target object W shown in FIG. 2 through opening patterns of a resist mask 62, by using the aforementioned plasma etching apparatus 1, will be discussed.

The gate valve 32 is opened to load the target object W into processing vessel 2 and then the object W is mounted on the electrostatic chuck 11. Subsequently, the gate valve 32 is closed, and the inside of the processing vessel 2 is depressurized by the gas exhaust unit 35. Thereafter, the valve 28 is opened to supply the etching gas, e.g., CF₃C≡CC₂F₅, O₂, and Ar, from the etching gas supply source 30, so that the pressure in the processing vessel 2 reaches a predetermined level, preferably greater than or equal to about 2.67 Pa, and more preferably, about 2.67 to about 4 Pa.

In such a condition, high frequency power is supplied to the upper electrode 21 and the susceptor 5, serving as the lower electrode, and thereafter, the etching gas is excited to generate a plasma to etch the SiO₂ film 61 on the target object W. Also, before or after supplying high frequency power to the upper and lower electrodes, a DC voltage is applied to the electrode 12 inside the electrostatic chuck 11 from the DC power supply 13 to electrostatically adsorb the target object W on the electrostatic chuck 11.

In the course of etching, a predetermined emission intensity is detected by using an endpoint detector (not shown), and based on the result, the etching is stopped.

In the present embodiment, the SiO₂ film 61 is etched through opening patterns of the resist mask 62, by using the plasma generated from an etching gas containing an aliphatic species such as C₅F₈, preferably, CF₃C≡CC₂F₅. Accordingly, it becomes possible to perform a plasma etching having a high selectivity to photoresist and/or suppressing an etch stop.

Further, the configuration of the etching apparatus is not limited to that of FIG. 1.

Hereinafter, the preferred embodiment of the present invention will be discussed in detail.

### EMBODIMENT 1

Frequency of the high frequency power source, which applies power to the upper electrode: 60 MHz

High frequency power applied to the upper electrode: 1800 W

Frequency of the high frequency power source, which applies power to the lower electrode: 2 MHz

High frequency power applied to the lower electrode: 1800 W

Temperature of the susceptor: −10° C.

Pressure inside the processing vessel: 2.67 Pa (20 mTorr)

Flow rates of etching gas components:

CF₃C≡CC₂F₅: 0.013 to 0.034 L/min (13 to 34 sccm);

O₂: 0.019 to 0.038 L/min (19 to 38 sccm); and

Ar: 0.5 L/min (500 sccm)

Under these etching process conditions, as shown in FIG. 2, the SiO₂ film on the target object W was etched via the opening patterns of the photoresist mask. The results are shown below in TABLE 1.

Further, in TABLE 1, the ‘etching penetration’ refers to whether or not a SiO₂ film having an opening size (or diameter) of 0.1 μm and a thickness of 2.0 μm could be etched. Namely, in case where the film could be penetrated by etching, ‘etching penetration’ is marked with ‘O’ whereas in case an etch stop occurs, it is marked with ‘X’ (same in TABLE 2).

TABLE 1

| | | | [CF₃C≡CC₂F₅ | Selectivity | | |
|---|---|---|---|---|---|---|
| | | | Flow rate]/ | to resist | | |
| | CF₃C≡CC₂F₅ | O₂ | [O₂ flow | (−) | | Etching |
| | flow rate | flow rate | rate] | Flat | Shoulder | penetration |
| No. | (×10⁻³ L/min) | (×10⁻³ L/min) | (−) | part | part | ◯ |
| 1 | 13 | 19 | 0.68 | 4.0 | 3.4 | ◯ |
| 2 | 15 | 19 | 0.79 | 5.9 | 3.8 | ◯ |
| 3 | 17 | 19 | 0.89 | 8.4 | 5.2 | ◯ |
| 4 | 27 | 30 | 0.90 | 9.9 | 4.7 | ◯ |
| 5 | 29 | 30 | 0.97 | 14.6 | 6.1 | ◯ |
| 6 | 27 | 27 | 1.00 | 17.5 | 5.9 | ◯ |
| 7 | 19 | 19 | 1.00 | 11.5 | 5.0 | ◯ |
| 8 | 21 | 19 | 1.11 | 18.8 | 6.2 | ◯ |
| 9 | 38 | 34 | 1.12 | 10.4 | 4.9 | ◯ |
| 10 | 25 | 19 | 1.32 | >8.0 | — | X |

Based on TABLE 1, it can be confirmed that in an area where the flow rate ratio of the CF₃C≡CC₂F₅ to the O₂ is in the range from about 0.79 to about 1.12, the selectivity to resist is high and the etch stop is unlikely to occur. Further, in case where the flow rate ratio of the CF₃C═CC₂F₅ to the O₂ is about 1.32, the etch stop is likely to occur, however, given that the selectivity to resist is high, for etching a film having a small aspect ratio, i.e., [thickness of film subject to etching)/[size (or diameter) of area subject to etching], it is possible to use the ratio. In addition, in case where the flow ratio of the CF₃C≡CC₂F₅ to the O₂ is about 0.68, even though the selectivity to resist is not high, given that the etch stop is unlikely to occur, a thick resist film with a high aspect ratio can be etched.

### EMBODIMENT 2

Frequency of the high frequency power source, which applies power to the upper electrode: 60 MHz

High frequency power applied to the upper electrode: 1800, 2170 W

Frequency of the high frequency power source, which applies power to the lower electrode: 2 MHz

High frequency power applied to the lower electrode: 1800, 1550 W

Temperature of the susceptor: 20, −10° C.

Pressure inside the processing vessel: 2 to 4 Pa (15 to 30 mTorr)

Flow rates of etching gas components:

CF₃C≡CC₂F₅: 0.013 to 0.025 L/min (13 to 25 sccm);

O₂: 0.019 L/min (19 sccm); and

Ar: 0.38 to 0.8 L/min (380 to 800 sccm)

Under these etching process conditions, the same sample as that of embodiment 1 was etched. The result is shown below in TABLE 2.

Further, ‘pressure’ in TABLE 2 refers to the ambient pressure around the target object W in the processing vessel, and ‘CF₃C≡CC₂F₅ partial pressure’ refers to the product of ‘pressure’ and ‘[CF₃C≡CC₂F₅ flow rate]/[total flow rate of etching gas]’.

TABLE 2

| | | O₂ | Ar | | CF₃C≡CC₂F₅ | | |
|---|---|---|---|---|---|---|---|
| | CF₃C≡CC₂F₅ | flow | flow | | partial | Selectivity | |
| | flow rate | rate | rate | pressure | pressure | to resist | etching |
| No. | (×10⁻³ L/min) | (×10⁻³ L/min) | (×10⁻³ L/min) | (Pa) | (×10⁻² Pa) | (−) | penetrability |
| 11 | 13 | 19 | 380 | 2.00 | 6.26 | 3.4 | ◯ |
| 12 | 13 | 19 | 500 | 2.67 | 6.53 | 3.4 | ◯ |
| 13 | 15 | 19 | 500 | 2.67 | 7.46 | 3.8 | ◯ |
| 14 | 17 | 19 | 500 | 2.67 | 8.40 | 4.7 | ◯ |
| 15 | 19 | 19 | 500 | 2.67 | 9.46 | 5.0 | ◯ |
| 16 | 21 | 19 | 800 | 4.00 | 10.0 | 4.8 | ◯ |
| 17 | 21 | 19 | 500 | 2.67 | 10.4 | 6.2 | X |
| 18 | 25 | 19 | 800 | 4.00 | 11.9 | 8.1 | X |

Based on TABLE 2, it can be confirmed that in an area where the CF₃C≡CC₂F₅ partial pressure is in the range from about 0.0746 to about 0.105 Pa, the selectivity to resist is high and the etch stop is likely to occur. Further, in case where the CF₃C≡CC₂F₅ partial pressure is about 0.119 Pa, even though the etch stop is unlikely to occur, given that the selectivity to resist is high, it is possible to apply the condition to etch a film which has a small aspect ratio [thickness of film subject to etching]/[distance across area subject to etching]. In addition, in case where the CF₃C≡CC₂F₅ partial pressure is about 0.0626 Pa, even though the selectivity to resist is not high, given that an etch stop is unlikely to occur, a thick resist film having a high aspect ratio can be sufficiently etched.

As mentioned above, in accordance with the present invention, a film to be etched, e.g., a SiO₂ film having patterns formed by a resist mask, is etched by the etching gas plasma in which the aliphatic C₅F₈ is the major component. Therefore, it is possible to perform plasma etching having a high selectivity to resist and/or suppressing the etch stop.

While the invention has been shown and described with respect to the preferred embodiment, it will be understood by those skilled in the art that various changes and modifications may be made without departing from the spirit and scope of the invention as defined in the following claims.

1. A plasma etching method, comprising the steps of:
exciting an etching gas introduced in a processing vessel into a plasma, the etching gas including an aliphatic C₅F₈ but not including CO; and
carrying out a plasma etching on a film on a target object accommodated in the processing vessel via opening patterns of a resist mask disposed on the film,
wherein the aliphatic C₅F₈ is 1,1,1,4,4,5,5,5-octafluoro-2-pentyne.

2. The plasma etching method of claim 1, wherein the etching gas further includes Ar.

3. The plasma etching method of claim 1, wherein the film is a SiO₂ film.

4. The plasma etching method of claim 1, wherein the etching gas further includes O₂ and a flow rate ratio of the 1,1,1,4,4,5,5,5-octafluoro-2-pentyne to the O₂ is in the range from about 0.79 to about 1.12.

5. The plasma etching method of claim 1, wherein a partial pressure of the 1,1,1,4,4,5,5,5-octafluoro-2-pentyne is in the range from about 0.0746 to about 0.105 Pa.

6. The plasma etching method of claim 1, wherein an inner pressure of the processing vessel is greater than or equal to about 2.67 Pa.

7. The plasma etching method of claim 1, wherein an inner pressure of the processing vessel is in the range from about 2.67 to about 4 Pa.

8. A plasma etching method, comprising the steps of:
exciting an etching gas introduced in a processing vessel into a plasma, the etching gas including an aliphatic C₅F₈, O₂, and an unreactive gas; and
carrying out a plasma etching on a film on a target object accommodated in the processing vessel via opening patterns of a resist mask disposed on the film,
wherein the aliphatic C₅F₈ is 1,1,1,4,4,5,5,5-octafluoro-2-pentyne.

9. The plasma etching method of claim 8, wherein the etching gas further includes Ar.

10. The plasma etching method of claim 8, wherein the etching gas does not include CO, substantially.

11. The plasma etching method of claim 8, wherein the film is a SiO₂ film.

12. The plasma etching method of claim 8, wherein a flow rate ratio of the 1,1,1,4,4,5,5,5-octafluoro-2-pentyne to the O₂ is in the range from about 0.79 to about 1.12.

13. The plasma etching method of claim 8, wherein a partial pressure of the 1,1,1,4,4,5,5,5-octafluoro-2-pentyne is in the range from about 0.0746 to about 0.105 Pa.

14. The plasma etching method of claim 8, wherein an inner pressure of the processing vessel is greater than or equal to about 2.67 Pa.

15. The plasma etching method of claim 8, wherein an inner pressure of the processing vessel is in the range from about 2.67 to about 4 Pa.

16. A plasma etching method, comprising the steps of:
exciting an etching gas introduced in a processing vessel into a plasma, the etching gas including 1,1,1,4,4,5,5,5-octafluoro-2-pentyne; and
carrying out a plasma etching on a film on a target object accommodated in the processing vessel via opening patterns of a resist mask disposed on the film.

17. The plasma etching method of claim 16, wherein the etching gas further includes Ar.

18. The plasma etching method of claim 16, wherein the etching gas does not include CO, substantially.

19. The plasma etching method of claim 16, wherein the film is a SiO₂ film.

20. The plasma etching method of claim 16, wherein a partial pressure of the 1,1,1,4,4,5,5,5-octafluoro-2-pentyne is in the range from about 0.0746 to about 0.105 Pa.

21. The plasma etching method of claim 16, wherein an inner pressure of the processing vessel is greater than or equal to about 2.67 Pa.

22. The plasma etching method of claim 16, wherein an inner pressure of the processing vessel is in the range from about 2.67 to about 4 Pa.

23. The plasma etching method of claim 16, wherein the etching gas includes O₂.

24. The plasma etching method of claim 23, wherein a flow rate ratio of the 1,1,1,4,4,5,5,5-octafluoro-2-pentyne to the O₂ is in the range from about 0.79 to about 1.12.
